(19) United States
(12) Patent Application Publication
(10) Pub. No.: US 2012/0034885 A1
(43) Pub. Date: Feb. 9, 2012

(54) BROADCASTING SYSTEM AND METHOD USING HUMAN BODY COMMUNICATION

(75) Inventors: Myung Hwan SEO, Guri-si (KR); Hyun Duk ROH, Seoul (KR); Kyu Tae KIM, Seoul (KR); Sung Kyum KIM, Seoul (KR); Jong Wu RYU, Suwon-si (KR); Ju Yeol PYO, Seoul (KR); Woo Gun HONG, Seoul (KR)

(73) Assignee: PANTECH CO., LTD., Seoul (KR)

(21) Appl. No.: 13/073,179

(22) Filed: Mar. 28, 2011

(30) Foreign Application Priority Data
Aug. 9, 2010 (KR) 10-2010-0076291

(51) Int. Cl. H04B 7/02; H05K 11/00

(52) U.S. Cl. 455/101; 455/344

(57) ABSTRACT

A transmitter includes a human body communication unit to detect an available broadcast channel; a channel setting unit to set the available broadcast channel to be connected; a broadcast data processing unit to generate a broadcast signal to be transmitted via the human body communication unit. A receiver includes a human body communication unit to receive broadcast signal; a channel setting unit to retrieve the broadcast channel to be connected; a broadcast processing unit to control the human body communication unit to receive the broadcast signal; and a broadcast data processing unit to generate broadcast data. A method for transmitting a broadcast signal includes detecting and setting the available broadcast channel to be connected; generating the broadcast signal; and broadcasting the broadcast signal via the broadcast channel. A method for receiving broadcast signal includes receiving, retrieving, and setting the broadcast channel; receiving the broadcast signal; and generating broadcast data.

### CROSS-REFERENCE TO RELATED APPLICATION

This application claims priority from and the benefit under 35 U.S.C. §119(a) of Korean Patent Application No. 10-2010-0076291, filed on Aug. 9, 2010, which is hereby incorporated by reference for all purposes as if fully set forth herein.

### BACKGROUND

1. Field

This disclosure relates to a system and a method for broadcasting data, and more particularly, to a system and a method for broadcasting data using a human body communication network.

2. Discussion of the Background

Signal transmission technologies to transmit various data between mobile terminals include a human body communication technology. The human body communication technology enables data communication using a human body as a transmission medium, similar to an electrical wire. The human body communication technology is based on the fact that a human body has properties of a conductor through which a weak electric current may flow, and that electrical signals are transmittable using the human body. Using this phenomenon, if a voltage is applied to the human body contacted with a transmitter or a receiver, an electric field of the surface of the human body changes, and the transmitter or receiver amplifies a small difference in voltage and reads electrical signals. In this instance, the electric current flowing through the human body is a maximum of about 500 μA, which may be equal to a level of an electric current used in a body fat scale, and may be harmless to the human body.

In other words, using an electric current running through a human body serving as a transmission medium similar to an electrical wire, the human body communication may enable transmission of various data, such as a picture, a moving image, a sound source, and the like, by making contact with a finger or shaking hands. However, the human body communication technology has been developed based on a one-to-one human relationship.

### SUMMARY

Exemplary embodiments of the present invention provide a broadcasting system and method for using a human body communication in a network between devices connected through a dielectric.

Additional features of the invention will be set forth in the description which follows, and in part will be apparent from the description, or may be learned by practice of the invention.

Exemplary embodiment of the present invention provide a transmitter of a broadcasting system using a human body communication, the transmitter including a human body communication unit to broadcast a broadcast signal through a connected human body or dielectric, and to detect an available broadcast channel; a channel setting unit to set the available broadcast channel as a broadcast channel to be connected based on a received input of a user or a reference condition; a broadcast data processing unit to encode, packetize, and modulate broadcast data to generate the broadcast signal; and a broadcast processing unit to control the human body communication unit to broadcast the broadcast signal via the broadcast channel.

Exemplary embodiment of the present invention provide a receiver of a broadcasting system using a human body communication, the receiver including a human body communication unit to receive a broadcast signal through a connected human body or dielectric; a channel setting unit to retrieve broadcast channels used to receive a broadcast signal through the human body communication unit and to set a broadcast channel to be connected, wherein the broadcast channel to be connected is set based on a received input of a user or a reference condition; and a broadcast processing unit to control the human body communication unit to receive the broadcast signal via the broadcast channel set to be connected, if a connection with the human body or dielectric is sensed; and a broadcast data processing unit to demodulate and decode the broadcast signal to generate broadcast data.

Exemplary embodiment of the present invention provide a method for transmitting a broadcast signal in a broadcasting system using a human body communication, including detecting broadcast channels available through a connected human body or dielectric; setting the available broadcast channel to be connected based on a received input of a user or a reference condition; encoding, packetizing, and modulating broadcast data to generate the broadcast signal; and broadcasting the broadcast signal via the broadcast channel.

Exemplary embodiment of the present invention provide a method for receiving a broadcast signal in a broadcasting system using a human body communication, including receiving a broadcast channel through a connected human body or dielectric; retrieving broadcast channels used for receiving the broadcast channel; setting a broadcast channel to be connected, wherein the broadcast channel to be connected is set based on a received input of a user or a reference condition; receiving the broadcast signal via the broadcast channel set to be connected, if a connection with the human body is sensed; and demodulating and decoding the broadcast signal to generate broadcast data.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 illustrates a structure of a broadcasting system using a human body communication according to an exemplary embodiment of the invention.

FIG. 2 illustrates a structure of a transmitter of the broadcasting system using a human body communication according to an exemplary embodiment of the invention.

FIG. 3 illustrates a structure of a receiver of the broadcasting system using a human body communication according to an exemplary embodiment of the invention.

FIG. 4 is a flowchart illustrating a broadcasting transmitting process using a human body communication by the transmitter of the broadcasting system according to an exemplary embodiment of the invention.

FIG. 5 is a flowchart illustrating a broadcast receiving process using a human body communication by the receiver of the broadcasting system according to an exemplary embodiment of the invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. It will be understood that for the purposes of this disclosure, “at least one of each” will be interpreted to mean any combination the enumerated elements following the respective language, including combination of multiples of the enumerated elements. For example, “at least one of X, Y, and Z” will be construed to mean X only, Y only, Z only, or any combination of two or more items X, Y, and Z (e.g. XYZ, XZ, YZ, X). Throughout the drawings and the detailed description, unless otherwise described, the same drawing reference numerals are understood to refer to the same elements, features, and structures. The relative size and depiction of these elements may be exaggerated for clarity, illustration, and convenience.

The exemplary embodiments of the invention relate to a system and a method for broadcasting data, and more particularly, to a system and a method for broadcasting data in a human body communication network.

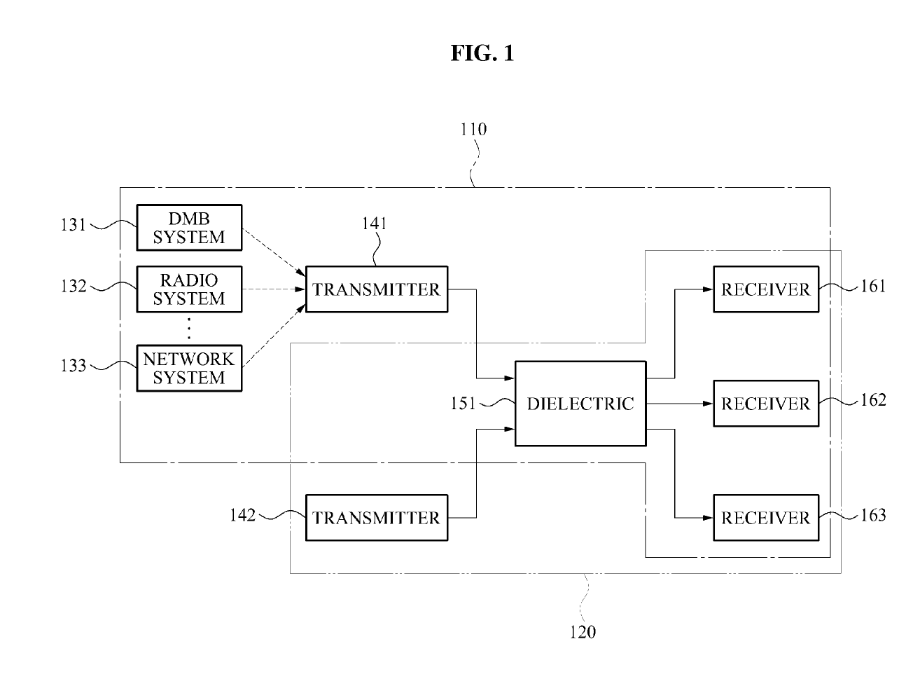

FIG. 1 illustrates a structure of a broadcasting system using a human body communication according to an exemplary embodiment of the invention. Referring to FIG. 1, the broadcasting system using a human body communication may broadcast data via a system connection broadcasting network (SBN) 110 or a personal broadcasting network (PBN) 120, depending on an origin of broadcast data.

A broadcasting system using the SBN 110 may broadcast data received from an external system, and a broadcasting system using the PBN 120 may broadcast data stored in a transmitter 142.

The PBN 120 may include the transmitter 142 to broadcast stored data through a dielectric 151, the dielectric 151 corresponding to a human body or a conductor through which an electric current flows, and receivers 161, 162, and 163 to receive a broadcast signal. In an example, the dielectric 151 may be a conductor through which an electric current flows, and serve as a transmission line to transmit a broadcast signal. In an example, the dielectric 151 may be a hand grip of a transportation vehicle, such as a subway train or a bus, an automobile handle, an armrest of a sofa or a chair, a label of an item on exhibit, a name plate of a product on a display stand, and the like.

The SBN 110 may include a digital multimedia broadcasting (DMB) system 131, a radio system 132, a network system 133, a transmitter 141, the dielectric 151, and the receivers 161, 162, and 163. As opposed to the PBN 120, the SBN 110 may receive broadcast data from an external system such as the DMB system 131, the radio system 132, or the network system 133. Accordingly, the transmitter 141 of the SBN 110 may broadcast data received from an external system through the dielectric 151.

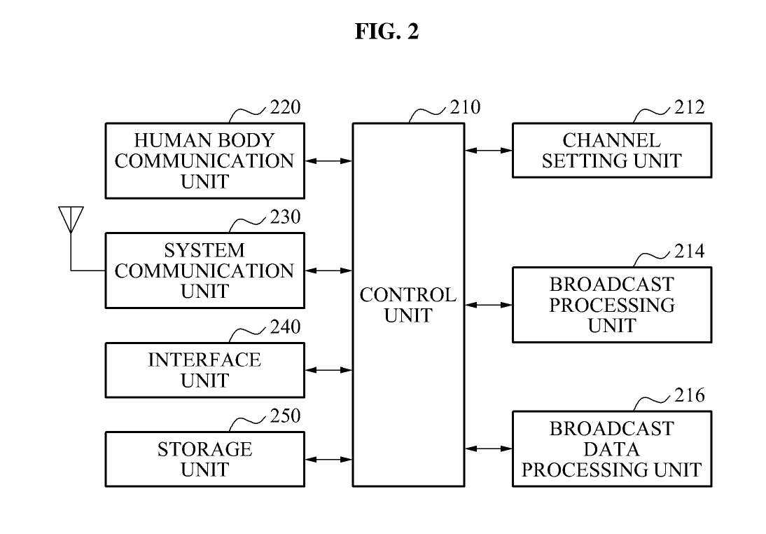

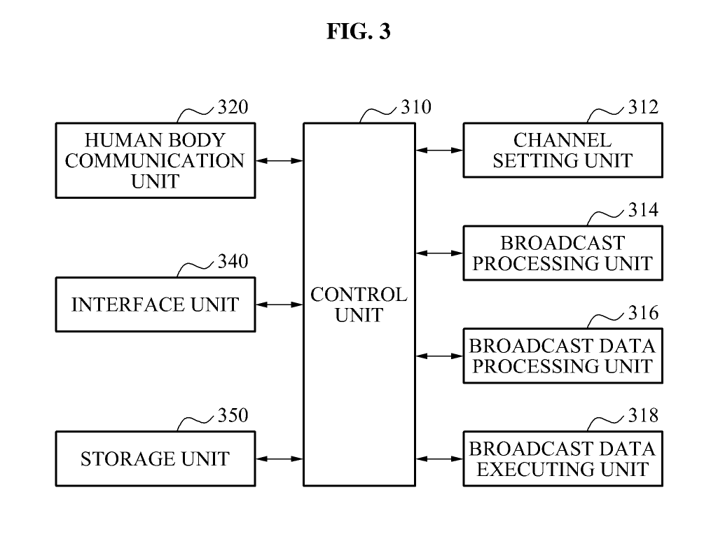

A receiver and a transmitter of the broadcasting system are described below with reference to FIG. 2 and FIG. 3.

FIG. 2 illustrates a structure of a transmitter of the broadcasting system using a human body communication according to an exemplary embodiment of the invention. The transmitter of FIG. 2 may be referenced to the transmitter 141 and the transmitter 142 of FIG. 1.

As shown in FIG. 2, the transmitter includes a control unit 210, a channel setting unit 212, a broadcast processing unit 214, a broadcast data processing unit 216, a human body communication unit 220, a system communication unit 230, an interface unit 240, and a storage unit 250.

The human body communication unit 220 may broadcast a broadcast signal through a connected human body or dielectric to provide a broadcast service. In the case of a group broadcast service for a specific designated user, the human body communication unit 220 may transmit and receive a signal to provide the group broadcast service. If the human body communication unit 220 broadcasts a signal, the human body communication unit 220 may broadcast a transmitting current through the human body or dielectric. Conversely, after the human body communication unit 220 receives a signal, the human body communication unit 220 may remove noise from the signal received through the human body and amplify the signal.

The system communication unit 230 may establish a wired or wireless communication connection to an external system, and receive broadcast data from the external system.

The interface unit 240 may provide an interface to a user to receive an input of the user. In addition, the interface unit 240 may also provide the user with setting information, control information, service information, and other similar information that may be provided during a broadcast service. In an example, the input received by the interface unit 240 may be category information of the broadcast data, or a group acceptance in response to a group request in the case of a group broadcast service.

The storage unit 250 may store data of multiple categories for broadcasting. Also, the storage unit 250 may store data received from the external system through the system communication unit 230.

The channel setting unit 212 may check whether broadcast channels are available through the human body communication unit 220. If broadcast channels are available through a connected human body communication unit 220, the channel setting unit 212 may set one of the available broadcast channels as a broadcast channel to broadcast service. In an example, the channel setting unit 212 may set a broadcast channel to be connected based on a received input of a user or a reference condition. Further, after a broadcast channel is set, the channel setting unit 212 may broadcast channel information including the category of the broadcast data detected by the broadcast processing unit 214 via the broadcast channel at a reference time interval.

In an example, the channel information may include information indicating whether the broadcast service is a group broadcast service. Here, the connected human body or dielectric corresponds to an available broadcast channel to transmit broadcast signals. In an example, the broadcast channel may be a channel having a bandwidth used to transmit one broadcast signal. Also, the available broadcast channel may have an unused bandwidth among available bandwidths, and the unused bandwidth may be used to transmit a broadcast signal without influencing another broadcast channel.

The broadcast data processing unit 216 may process the broadcast data to generate a broadcast signal. The broadcast data processing unit 216 may encode the broadcast data and packetize the encoded broadcast data to generate a broadcast data packet. In addition, the broadcast data processing unit 216 may further modulate the broadcast data packet to generate a broadcast signal.

The broadcast processing unit 214 may detect category information of the broadcast data if a broadcast event occurs, and determine whether the broadcast data is a broadcast data for a group broadcast service. Here, the category of the broadcast data may be used to classify a type and a genre of the broadcast data. In an example, the categories of broadcast data may include a moving image, radio data, audio data, text, and the like. Also, the broadcast data may be further classified, leading to a hierarchical classification. For example, if broadcast data is a moving image, the broadcast data may be further classified into an action type, a romance type, a suspense type, a drama type, and the like, based on genre information.

If the broadcast data does not include data related to a group broadcast service, the broadcast processing unit 214 may control the human body communication unit 220 to broadcast the broadcast signal generated by the broadcast data processing unit 216 to a receiver via the broadcast channel set to be connected.

If the broadcast data includes data related to a group broadcast service, the broadcast processing unit 214 may receive a group request signal, determine whether to accept the group request signal as a group, and transmit a group response signal including a group accept result to a receiver which transmitted the group request signal. The broadcast processing unit 214 may further receive connection identity information from a receiver accepted as a group, and set information of the corresponding receiver to provide the receiver with a group broadcast service using the connection identity information. Then, the broadcast processing unit 214 may control the human body communication unit 220 to broadcast the broadcast signal to a receiver via the broadcast channel set to be connected. In an example, the group broadcast service may be a broadcast service provided to the users belonging to a group. The group request signal may be a signal used to make a request to join a group and to receive a group broadcast service that is provided to a receiver by the transmitter. Further, group acceptance or rejection may be determined based on an input of a user of the transmitter or a reference acceptance condition. The reference acceptance condition may include, for example, a case where the number of group members is 10 or less.

The control unit 210 may control the operation of a transmitter. In an example, the control unit 210 may perform functions of the channel setting unit 212, the broadcast processing unit 214, and the broadcast data processing unit 216. Accordingly, although the present embodiment describes each function of the enumerated units individually, the control unit 210 may perform some or all of the functions of the enumerated units in actual products. Alternatively, the control unit 210 may perform a portion of one or more functions of the enumerated units.

FIG. 3 illustrates a structure of a receiver of the broadcasting system using a human body communication according to an exemplary embodiment of the invention.

As shown in FIG. 3, the receiver includes a control unit 310, a channel setting unit 312, a broadcast processing unit 314, a broadcast data processing unit 316, a broadcast data executing unit 318, a human body communication unit 320, an interface unit 340, and a storage unit 350.

The human body communication unit 320 may receive a broadcast signal through a connected human body or dielectric, including channel information. The human body communication unit 320 may transmit and receive a signal for a group broadcast service to and from a specific designated user. The human body communication unit 320 may receive a transmitting current including transmission data through the human body or a dielectric. Also, the human body communication unit 320 may remove noise from a signal received through the human body and amplify the signal.

The interface unit 340 may provide an interface with a user to receive an input of the user, and provide the user with setting information, control information, service information, and other similar information that may provided during a broadcast service. In an example, the interface unit 340 may receive an input of a category of broadcast data to be received from the user, and select a broadcast channel to be connected.

The storage unit 350 may store the received broadcast data.

If a connection with the human body or dielectric is sensed, the channel setting unit 312 may check whether broadcast channels are available for the set category of the broadcast data. In addition, the channel setting unit 312 also retrieves broadcast channels used to receive a broadcast signal including channel information through the human body communication unit. In an example, the channel setting unit 312 may check whether the broadcast channel is used to broadcast the broadcast data of the set category using channel information and retrieves broadcast channels used to receive the broadcast signal. Information indicating whether the broadcast service is a group broadcast service may be included in the channel information.

The channel setting unit 312 may set a broadcast channel to be connected based on a received input of a user or a reference condition among the broadcast channels according to the category of the broadcast data.

If the broadcast data processing unit 316 receives a modulated broadcast data packet as a broadcast signal, the broadcast data processing unit 316 may demodulate the modulated broadcast data packet, arrange the broadcast data packet in order, and pass the broadcast data packet, which may still be encoded. Also, the broadcast data processing unit 316 may decode the encoded broadcast data into broadcast data.

The broadcast data executing unit 318 may execute the broadcast data using an application corresponding to a category of the broadcast data under the control of the broadcast processing unit 314.

If a connection with the human body or dielectric is sensed, the broadcast processing unit 314 may set a category of the broadcast data based on an input of a user or a reference condition, and check whether the broadcast channel connected through the channel setting unit 312 is a broadcast channel to provide a group broadcast service.

If the connected broadcast channel is not a broadcast channel to provide a group broadcast service, the broadcast processing unit 314 may control the human body communication unit 320 to receive a broadcast signal via the connected broadcast channel, control the broadcast data processing unit 316 to demodulate and decode the received broadcast signal to generate broadcast data, and control the broadcast data executing unit 318 to execute the broadcast data.

If the connected broadcast channel is a broadcast channel to provide a group broadcast service, the broadcast processing unit 314 may transmit a group request signal to the transmitter and receive a group response signal including a group accept result from the transmitter. If the group request is accepted, the broadcast processing unit 314 may transmit connection identity information to the transmitter and set information of the transmitter for transmitting broadcast data to receive a group broadcast service. Then, the broadcast processing unit 314 may control the human body communication unit 340 to receive a broadcast signal of the group broadcast service via the connected broadcast channel, control the broadcast data processing unit 316 to demodulate and decode the broadcast signal to generate broadcast data, and control the data executing unit 318 to execute the broadcast data.

The control unit 310 may control an operation of the receiver. The control unit 310 may perform functions of the channel setting unit 312, the broadcast processing unit 314 and the broadcast data executing unit 318. Accordingly, although the present embodiment describes each function of the enumerated units individually, the control unit 310 may perform one or more of the functions of those units in actual products. Also, the control unit 310 may perform a portion of one or more functions of the same units.

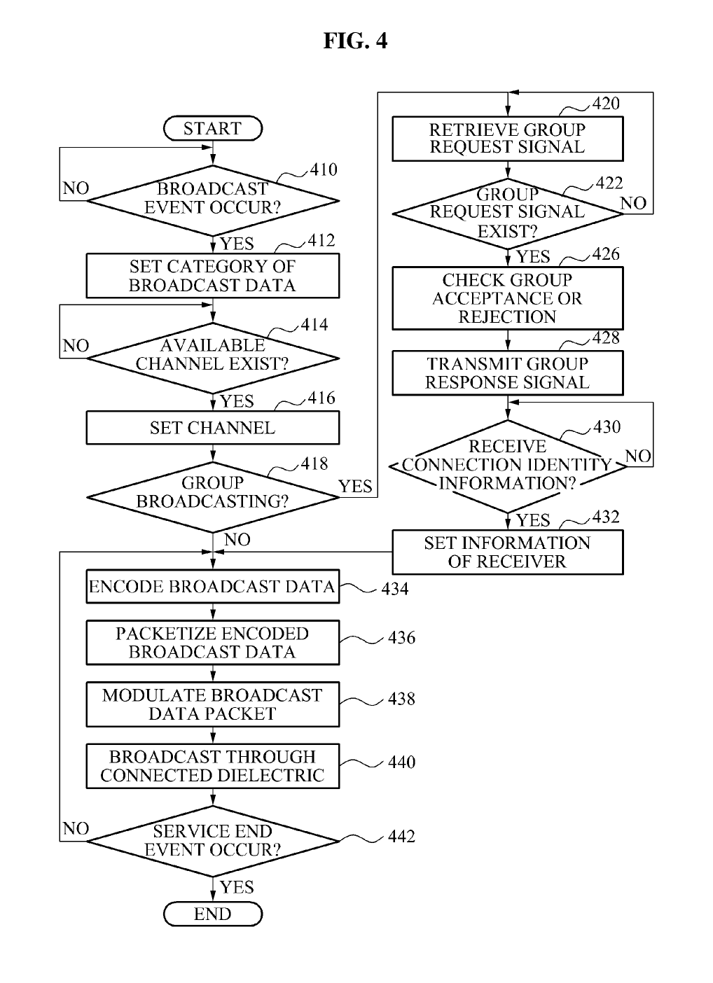

Hereinafter, a broadcasting method using a human body communication by the transmitter of the broadcasting system according to an exemplary embodiment of the invention is described below with reference to FIG. 4.

FIG. 4 is a flowchart illustrating a broadcasting process using a human body communication by the transmitter of the broadcasting system according to an exemplary embodiment of the invention.

Referring to FIG. 4, if the transmitter senses an occurrence of a broadcast event in operation 410, the transmitter sets a category of broadcast data in operation 412. In an example, the category of broadcast data may include a moving image, radio data, audio data, text, and the like.

In operation 414, the transmitter checks whether broadcast channels are available for broadcasting.

If the broadcast channels are determined to be available in operation 414, the transmitter sets one of the available broadcast channels as a channel for broadcasting in operation 416. In an example, the broadcast channel to be connected is set based on a received input of a user or a reference condition. Further, after the broadcast channel is set, the transmitter broadcasts channel information including category information of the broadcast data via the broadcast channel at a reference time interval.

In operation 418, the transmitter checks whether the broadcast service is a group broadcast service. In an example, the group broadcast service may be a broadcast service to transmit a broadcast signal to a receiver permitted by the transmitter.

If the broadcast service is determined not to be a group broadcast service in operation 418, the transmitter encodes the broadcast data in operation 434, and packetizes the encoded broadcast data in operation 436. Then, the transmitter modulates the broadcast data packet in operation 438, and broadcasts the modulated broadcast data packet through the connected human body or dielectric in operation 440.

In operation 442, the transmitter checks whether a broadcast service end event has occurred. If the broadcast service end event has not occurred in operation 442, the transmitter returns to operation 434 and repeats operation 434, operation 436, operation 438, and operation 440 until the broadcast service ends. If the broadcast service end event has occurred in operation 442, the transmitter terminates the algorithm of FIG. 4.

Alternatively, if the broadcast service is determined to be a group broadcast service in operation 418, the transmitter seeks to retrieve receipt of a group request signal in operation 420 and checks whether group request signal has been received in operation 422. If it is determined that the group request signal has not been received in operation 422, the transmitter returns to operation 420 and wait for a group request signal.

If the group request signal has been received in operation 422, the transmitter may determine whether to accept a requested receiver as a group in operation 426. The group acceptance or rejection may be determined based on an input of a user of the transmitter or a reference acceptance condition. The reference acceptance condition may include, for example, a case where the number of group members is 10 or less, and the like.

In operation 428, the transmitter may transmit a group response signal including a group acceptance result to a receiver which transmitted the group request signal. If the transmitter receives connection identity information from the accepted receiver in operation 430, the transmitter may set information of the receiver to provide the receiver with a group broadcast service using the connection identity information in operation 432, and proceed with operation 434.

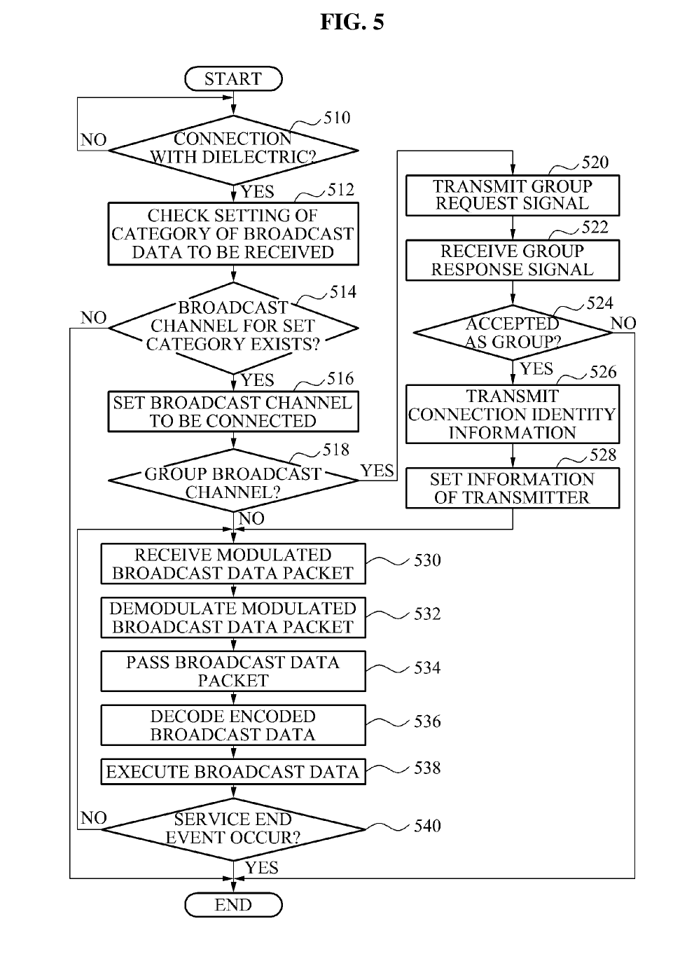

FIG. 5 is a flowchart illustrating a broadcast receiving process using a human body communication by the receiver of the broadcasting system according to an exemplary embodiment of the invention.

Referring to FIG. 5, if a connection with a human body or a dielectric is sensed in operation 510, the receiver may detect a category setting of broadcast data to be received, in operation 512. In an example, the category of broadcast data to be received may be detected based on an input of a user of the receiver or a reference category setting.

In operation 514, the receiver checks whether broadcast channels are available for the set category of the broadcast data through a human body communication. Further, the receiver may retrieve the broadcast channels through the connected human body communication or dielectric. In an example, a determination of whether the broadcast data of the set category is transmitted via the broadcast channels may be checked using channel information. If broadcast channels for the set category of the broadcast data are not available in operation 514, the receiver may terminate the algorithm of FIG. 5.

If broadcast channels for the set category of the broadcast data are available in operation 514, the receiver sets a broadcast channel to be connected based on a received user input or a reference condition in operation 516.

If the broadcast channel to be connected is not a broadcast channel for a group broadcast service in operation 518, the receiver may receive a modulated broadcast data packet through the connected human body or dielectric, in operation 530. Next, the receiver may demodulate the modulated broadcast data packet into a broadcast data packet in operation 532, and may arrange the broadcast data packet in order, and may pass the broadcast data packet in operation 534.

In operation 536, the receiver decodes the encoded broadcast data into broadcast data. In operation 538, the receiver executes the broadcast data.

In operation 540, the receiver may check whether a broadcast service end event occurred. If the broadcast service did not end in operation 540, the receiver may return to operation 530 and repeat operation 530, operation 532, operation 534, operation 536, and operation 538 until the broadcast service ends. If the broadcast service ended in operation 540, the receiver may terminate the algorithm of FIG. 5.

If the broadcast channel to be connected is a broadcast channel for a group broadcast service in operation 518, the receiver transmits a group request signal via the broadcast channel to be connected in operation 520.

In operation 522, the receiver receives a group response signal including a group accept result from the transmitter. In operation 524, the receiver detects group acceptance or rejection from the group accept result included in the group response signal. If the receiver is not accepted as a group in operation 524, the receiver terminates the algorithm of FIG. 5.

If the receiver is accepted as a group in operation 524, the receiver transmits connection identity information to the transmitter in operation 526, sets information of the transmitter to receive a group broadcast service in operation 528, and proceed with operation 530.

The broadcasting system according to the exemplary embodiments of the invention may include a wide range of applications as follows.

First, the broadcasting system may be applied to a small-sized broadcast network including users of mobile terminals having receivers and transmitters. In an example, the small-sized broadcast network may enable information transmission in, for example, a presentation, a discussion, a conference, marketing, and the like.

Second, the broadcasting system may be applied such that broadcast data, for example, broadcasting, route, station guidance, news, and the like, is broadcasted to a receiver of a user taking hold of a hand grip of a public transportation vehicle, which may be used as a dielectric. In an example, public transportation vehicles include a subway train, a bus, and the like.

Third, the broadcasting system may be applied such that a transmitter in an indoor environment, such as a café, a classroom, a sofa, a library, an airplane, and the like, transmits and receives broadcast data to and from users of a receiver connected through a dielectric. In an example, broadcast data may include video data, audio data, an image and the like.

Fourth, the broadcasting system may be applied such that a transmitter in a public environment, such as a museum, an exhibition, a zoo, an aquarium, and the like, broadcasts broadcast data to a user of a receiver connected through a dielectric. In an example, broadcast data may include information of an item on exhibit, an art, an animal, and the like.

Fifth, the broadcasting system may be applied such that a transmitter on a stand, which may be dielectric, in a retail market broadcasts information of a product on the stand to a user of a receiver, if the user touches a reference portion of the dielectric stand.

Sixth, the broadcasting system may be applied such that additional information such as a manual of a specific product is transmitted to a receiver of a user connected through a dielectric.

Seventh, the broadcasting system may be applied such that a transmitter in a car broadcasts driving information and car information to a receiver of a user taking hold of a handle, which may be a dielectric, to correct a bad habit and to remove potential danger.

Eighth, the broadcasting system may be applied to a portion or any combination of the above-disclosed exemplary applications.

The embodiments of the present invention provide a system and a method for broadcasting data to a receiver in a human body communication network through a human body and a dielectric. The broadcasting using a human body communication may reduce a waste of frequency resources, may implement a system of low power consumption on an air interface, and may selectively allow a limited service or a multi-purpose service through a group broadcasting as an authentication process.

The exemplary embodiments according to the present invention may be recorded in non-transitory computer-readable media including program instructions to implement various operations embodied by a computer. The media may also include, alone or in combination with the program instructions, data files, data structures, and the like. The media and program instructions may be those specially designed and constructed for the purposes of the present invention, or they may be of the kind well-known and available to those having skill in the computer software arts.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A transmitter of a broadcasting system using a human body communication, the transmitter comprising:
a human body communication unit to broadcast a broadcast signal through a connected human body or dielectric, and to detect an available broadcast channel;
a channel setting unit to set the available broadcast channel as a broadcast channel to be connected based on a received input of a user or a reference condition;
a broadcast data processing unit to encode, packetize, and modulate broadcast data to generate the broadcast signal; and
a broadcast processing unit to control the human body communication unit to broadcast the broadcast signal via the broadcast channel.

2. The transmitter of claim 1, wherein the broadcast data comprises at least one of a moving image, radio data, audio data, and text.

3. The transmitter of claim 1, wherein the broadcast processing unit sets a category of the broadcast data, and the channel setting unit broadcasts channel information comprising the category of the broadcast data via the broadcast channel at a reference time interval.

4. The transmitter of claim 1, wherein the broadcast processing unit receives a group request from a receiver, determines whether to accept the receiver as a group, and provides the broadcast service to the receiver if the receiver is accepted as the group.

5. The transmitter of claim 4, wherein the channel setting unit broadcasts channel information indicating the group broadcast service via the broadcast channel at a reference time interval.

6. The transmitter of claim 1, further comprising:
a system communication unit to receive the broadcast data from an external system using a wired or wireless communication.

7. A receiver of a broadcasting system using a human body communication, the receiver comprising:
a human body communication unit to receive a broadcast signal through a connected human body or dielectric;
a channel setting unit to retrieve broadcast channels used to receive a broadcast signal through the human body communication unit, and to set a broadcast channel to be connected, wherein the broadcast channel to be connected is set based on a received input of a user or a reference condition;
a broadcast processing unit to control the human body communication unit to receive the broadcast signal via the broadcast channel set to be connected, if a connection with the human body or dielectric is sensed; and
a broadcast data processing unit to demodulate and decode the broadcast signal to generate broadcast data.

8. The receiver of claim 7, wherein the broadcast processing unit sets a category of the broadcast data based on a received input of a user or a reference condition, and the channel setting unit retrieves broadcast channels used to set the category of the broadcast data.

9. The receiver of claim 8, wherein the channel setting unit retrieves broadcast channels used to set the category of the broadcast data based on a category of broadcast data of broadcast channel included in channel information received.

10. The receiver of claim 7, wherein if a group broadcast service is provided via the broadcast channel set to be connected, the broadcast processing unit transmits a group request to a transmitter, and if group acceptance is received, the broadcast processing unit transmits connection identity information to the transmitter, to receive a broadcast service provided to a receiver accepted as a group.

11. The receiver of claim 10, wherein the channel setting unit detects that the group broadcast service is provided using channel information received via the broadcast channel set to be connected.

12. The receiver of claim 7, further comprising:
a broadcast data executing unit to execute the broadcast data using an application corresponding to the category of the broadcast data.

13. A method for transmitting a broadcast signal in a broadcasting system using a human body communication, the method comprising:
detecting broadcast channels available through a connected human body or dielectric;
setting the available broadcast channel to be connected based on a received input of a user or a reference condition;
encoding, packetizing, and modulating broadcast data to generate the broadcast signal; and
broadcasting the broadcast signal via the broadcast channel.

14. The method of claim 13, further comprising determining whether the broadcast service to be transmitted is a group broadcast service, wherein if a group broadcast service is transmitted via the broadcast channel set to be connected, the broadcast signal comprises:
receiving a group request from a receiver;
determining whether to accept as a group; and
transmitting the broadcast signal to a receiver accepted as the group.

15. The method of claim 13, further comprising:
receiving the broadcast data from an external system using a wired or wireless communication.

16. A method for receiving a broadcast signal in a broadcasting system using a human body communication, comprising:
receiving a broadcast channel through a connected human body or dielectric;
retrieving broadcast channels used for receiving the broadcast channel;
setting a broadcast channel to be connected, wherein the broadcast channel to be connected is set based on a received input of a user or a reference condition;
receiving the broadcast signal via the broadcast channel set to be connected, if a connection with the human body is sensed; and
demodulating and decoding the broadcast signal to generate broadcast data.

17. The method of claim 16, further comprising:
setting a category of the broadcast data based on a received input of a user or a reference condition,
wherein setting the broadcast channel to be connected comprises retrieving broadcast channels for the set category of the broadcast data, and setting a broadcast channel to be connected based on the received input of the user or the reference condition.

18. The method of claim 16, further comprising:
if a group broadcast service is provided via the broadcast channel set to be connected, transmitting a group request to a transmitter; and
if group acceptance is received, transmitting connection identity information to a transmitter to receive the group broadcast service.

19. The method of claim 16, further comprising:
executing the broadcast data.
